(19) United States
(12) Patent Application Publication
(10) Pub. No.: US 2025/0189557 A1
(43) Pub. Date: Jun. 12, 2025

(54) SOCKET APPARATUS FOR SECURE PLACEMENT OF CHIP PACKAGE

(71) Applicant: Microsoft Technology Licensing, LLC, Redmond, WA (US)

(72) Inventors: Manoj B KESHAVAN, San Jose, CA (US); Guosong LIN, Marietta, GA (US); Jon Thomas WOODYARD, Livermore, CA (US)

(21) Appl. No.: 18/532,867

(22) Filed: Dec. 7, 2023

(51) Int. Cl. G01R 1/04; G01R 31/28; H05K 1/18

(52) U.S. Cl. CPC G01R 1/045; G01R 1/0466; G01R 31/2896; H05K 1/181

(57) ABSTRACT

The present disclosure relates to a socket apparatus that includes a socket cavity sized and configured to receive a chip package. The socket apparatus further includes a plurality of base contacts on a bottom surface of the socket apparatus, the plurality of base contacts being mountable on a circuit board. The socket apparatus further includes a plurality of pins positioned across a top surface of the socket apparatus opposite the bottom surface, each pin of the plurality of pins having a location that is referenced relative to a datum reference. The datum reference is positioned in a first corner of the socket apparatus to improve alignment accuracy between socket pins and package pads.

### BACKGROUND

Current trends in assembling a circuit board including chip packages often include socket structures that provide an interconnect on which chip packages can be placed and connected to other components on the circuit board. An advantage of utilizing a socket is the ability to separate and reconnect the circuit board and the chip package during testing and assembly of an electronic device. In many cases, sockets provide flexibility in the test and validation process. For example, CPUs have much longer lead times for design and development, and the use of sockets allows for the testing of PCBs to proceed independently of the CPU. In addition, subsystem level tests that don't require the CPU can also be carried out earlier in the development cycle, saving valuable time.

Utilizing sockets additionally allows for the replacement of malfunctioning chips or chip updates over time. In this way, only a specific chip package needs to be replaced, rather than replacing an entire circuit board including multiple chips that may be working just fine or that do not need to be updated. Indeed, sockets provide a convenient and highly functional mechanism for enabling manufacture of circuit boards and chip packages in a manner that is flexible and allows for more cost-efficient service and maintenance of an electronic device.

Manufacturing and assembling circuit boards and packages thereon have inherently tolerances. For example, in order to ensure that packages fit into socket openings, socket openings are typically designed to be larger than the package size in nominal conditions. The resulting free play that exists between the package and the socket is governed by the dimensional tolerances of each of the two components. Once placed within the socket structure, packages are often prone to movement and rotation within the socket structure which could cause electrical opens where signal path between a circuit board and a chip is broken and may ultimately result in less than reliable connections between the electrical components on the chip package(s) and corresponding components on a circuit board. These and other problems exist in providing connections between packages and circuit boards, particularly when using socket structures as a medium for connecting these components.

The subject matter in the background section is intended to provide an overview of the context for the subject matter disclosed herein. The subject matter discussed in the background section should not be assumed to be prior art merely as a result of its mention in the background section. Similarly, a problem mentioned in the background section or associated with the subject matter of the background section should not be assumed to have been previously recognized in the prior art.

### SUMMARY

One or more embodiments described herein relate to a socket apparatus. The socket apparatus includes a socket cavity sized and configured to receive a chip package. The socket apparatus additionally includes a plurality of base contacts on a bottom surface of the socket apparatus, the plurality of base contacts being mountable on a circuit board. The socket apparatus further includes a plurality of pins positioned across a top surface of the socket apparatus opposite the bottom surface, each pin of the plurality of pins having a location that is referenced relative to a datum reference. The datum reference is positioned in a first corner of the socket apparatus. In one or more implementations, the pins and base contacts are part of a single structure (e.g., one piece) extending from a top surface to a bottom surface of the socket apparatus.

In one or more embodiments, the plurality of pins include a plurality of uniformly oriented pins deflecting in a uniform direction and parallel to one another, such that when a plurality of electrical pads of the chip package come into contact with the plurality of uniformly oriented pins and a load is applied to the top surface of the socket apparatus, the plurality of uniformly oriented pins are configured to wipe in a uniform direction towards a first corner (e.g., an A1 corner) of the socket apparatus. In one or more embodiments, the plurality of uniformly oriented pins are configured to wipe between initial contact points and final resting points in which a direction between the initial contact points and the final resting points is towards the first corner of the socket apparatus parallel to a diagonal of the socket cavity. In one or more embodiments, each initial contact point and each final resting point of the plurality of uniformly oriented pins are within an area of a corresponding electrical pad from the plurality of electrical pads. In one or more embodiments, a top portion of each uniformly oriented pin of the plurality of uniformly oriented pins is angled in parallel to a diagonal of the socket cavity passing through and towards the first corner of the socket apparatus, wherein an angling of the top portion is parallel to the diagonal of the socket cavity and causes the biasing pin to flex in a uniform direction parallel to the diagonal towards the first corner while applying the load to the top surface of the socket apparatus.

In one or more embodiments, the socket cavity includes a partial enclosure of the top surface of the socket apparatus, the partial enclosure including at least a corner structure around the first corner of the socket apparatus. In one or more embodiments, the socket cavity includes a full enclosure of the socket apparatus.

In one or more embodiments, the plurality of base contacts and the plurality of pins are part of a continuous member having solder balls added to the base plurality of base contacts to solder the continuous member to the circuit board. In one or more embodiments, the socket apparatus has a first size, and wherein the chip package has a second size having a set of dimensions that are smaller than the first size such that the chip package fits within the socket cavity of the socket apparatus. In one or more embodiments, the socket apparatus includes a ball grid array (BGA) (e.g., BGA packaging). In one or more embodiments, the chip package is a land grid array (LGA) package.

One or more embodiments also relate to a circuit board package. The circuit board package may include a socket apparatus having any of the features described above. In addition, the circuit board package may include a circuit board and a socket apparatus mounted to the circuit board via a plurality of base contacts on a bottom surface of the socket apparatus. In one or more embodiments, the socket apparatus includes a socket cavity sized and configured to receive a chip package and a plurality of pins positioned across a top surface of the socket apparatus opposite the bottom surface, each pin of the plurality of pins having a location that is referenced relative to a datum reference. The datum reference is positioned in a first corner of the socket apparatus.

In one or more embodiments, the plurality of pins include a plurality of uniformly oriented pins deflecting in a uniform direction and parallel to one another, such that when a plurality of electrical pads of the chip package come into contact with the plurality of uniformly oriented pins and a load is applied to the top surface of the socket apparatus, the plurality of uniformly oriented pins are configured to wipe in a uniform direction towards the first corner of the socket apparatus. In one or more embodiments, the plurality of pins is configured to wipe between an initial contact point and a final resting point in which a direction between the initial contact point and the final resting point is parallel to a diagonal of the socket cavity passing through and toward the first corner of the socket apparatus.

In one or more embodiments, each electrical pad of a plurality of electrical pads of the chip package has a location that is referenced relative to the datum reference. In one or more implementations, the datum reference is positioned in the first corner of the chip package that aligns with the first corner of the socket apparatus when the chip package is placed within the socket cavity. In one or more embodiments, the first corner of the chip package and the first corner of the socket apparatus is a same physical corner. In one or more embodiments, the chip package is a land grid array (LGA) package and the socket apparatus includes BGA packaging. In one or more implementations, the socket apparatus is a surface mount technology (SMT) socket.

One or more embodiments described herein relate to a method of facilitating an electrical connection between a circuit board and a chip package. The method includes mounting a socket apparatus to the circuit board via a plurality of base contacts on a bottom surface of the socket apparatus, the socket apparatus including a plurality of pins positioned across a top surface of the socket apparatus opposite the bottom surface, each pin of the plurality of pins having a location that is referenced relative to a datum reference. The datum reference is positioned in a first corner of the socket apparatus. The method further includes placing the chip package within a socket cavity of the socket apparatus to position a plurality of electrical pads on the chip package in contact with the plurality of pins on the top surface of the socket apparatus. The method further includes applying a biasing load to the chip package such that the first corner of the chip package aligns with the first corner of the socket apparatus.

In one or more embodiments, the plurality of pins comprises a plurality of uniformly oriented pins deflecting in a uniform direction and parallel to one another, such that when a plurality of electrical pads of the chip package come into contact with the plurality of uniformly oriented pins and the biasing load is applied to the top surface of the socket apparatus, the plurality of uniformly oriented pins are configured to wipe in a uniform direction towards the first corner of the socket apparatus. In one or more embodiments, the biasing load is caused by a combination of physical placement of the chip package in the first corner of the socket apparatus and wiping of the plurality of uniformly oriented pins in parallel to a diagonal of the socket cavity passing through and towards the first corner of the socket apparatus. In one or more embodiments, plurality of uniformly oriented pins are configured to wipe between an initial contact point and a final resting point in which a direction between the initial contact point and the final resting point is parallel to a diagonal of the socket cavity passing through and towards the first corner of the socket apparatus.

### BRIEF DESCRIPTION OF THE DRAWINGS

FIG. 1 illustrates an example of a socket apparatus, in accordance with one or more embodiments.

FIG. 2 illustrates an example of a circuit board package, in accordance with one or more embodiments.

FIGS. 3A and 3B illustrate a sideview of a circuit board package establishing an electrical connection with a chip package through a socket, in accordance with one or more embodiments.

FIG. 4 illustrates a top-down view of a socket apparatus and a chip package having a datum reference positioned in the first corner of the socket apparatus, in accordance with at least one or more embodiments.

FIG. 5 illustrates an example of a corner datum reference, in accordance with at least one or more embodiments.

FIG. 6 illustrates an example of having different sized sockets and different sized chip packages, in accordance with one or more embodiments.

FIG. 7 illustrates a series of acts for facilitating an electrical connection between a circuit board and a chip package, in accordance with one or more embodiments.

### DETAILED DESCRIPTION

The present disclosure relates generally to a socket apparatus that provides a mechanism for electrically coupling a chip package with components on a circuit board in a secure and reliable manner. In particular, features described herein relate to a socket apparatus (or simply, “socket”) that is mountable to a circuit board (e.g., a printed circuit board (PCB), a motherboard) and which is configured to receive a chip package within a cavity of the socket and which includes features and functionality that cause a plurality of pins on the socket to maintain a reliable and secure connection or contact with a chip package that is placed into the cavity of the socket.

By way of example, and as will be discussed in further detail below, a socket may include a socket cavity that is sized and configured to receive a chip package. The socket includes a plurality of base contacts on a bottom surface of the socket that are mountable on a circuit board. The socket additionally includes a plurality of pins (e.g., uniformly oriented pins) across a top surface of the socket (e.g., on the same structure as the base contacts) where each pin of the plurality of pins has a location that is referenced or otherwise positioned on the top surface of the socket relative to a datum reference. In one or more implementations described herein, the datum reference refers to an origin or point of reference in a first corner (e.g., a top-left, or A1 corner) of the socket. In addition, it will be appreciated that the pins on the top surface of the socket structure and the base contacts on the bottom surface of the socket structure may be part of the same continuous member in which solder balls are added to the base contacts to enable soldering or otherwise connecting the structure to the circuit board.

In addition to characteristics of the socket, and as will be discussed in further detail herein, the present disclosure relates to a method or series of acts for facilitating an electrical connection between a circuit board and a chip package. This includes mounting a socket to the circuit board via a plurality of base contacts where the socket includes features discussed above (e.g., the plurality of pins having locations relative to the datum). The chip package may be placed within a socket cavity of the socket to position a plurality of electrical pads on the chip package in contact with corresponding pins from the socket. A biasing load may additionally be applied to the chip package such that the first corner of the chip package aligns with a first corner of the socket.

The features and functionalities described herein provide a number of advantages and benefits over conventional approaches and systems. For example, the systems described herein provide features and functionality related to a socket apparatus (or simply, “socket”) that securely and reliably facilitates an electrical connection between electrical pads of a chip package and components on a circuit board by way of a plurality of pins on the socket. It will be appreciated that the advantages and benefits discussed herein are provided by way of example and are not intended to be an exhaustive list of all possible advantages and benefits of implementations of the socket and methods described herein.

For example, in one or more embodiments, the socket includes a plurality of uniformly oriented pins that deflect in the same direction and parallel to one another. The orientation of the pin deflection is such that when a package is placed and loaded in the socket, the net line of action of the resultant frictional force imparted by the plurality of contacts on the package passes through the top left (or A1 corner) of the socket. Indeed, in one or more embodiments, the orientation of a long axis of the pads on the chip package may coincide with or be parallel to the diagonal of the socket cavity such that the qiping direction of the pins is along the long axis of the corresponding chip package pads.

Orienting the pins in such a manner as discussed herein causes a wiping of the plurality of pins on the corresponding package pads, which too are oriented such that the direction of wiping of the plurality of pins is along the long axis of the package pads. When the chip package is loaded in the socket under the scenario described herein, the net effect is a biasing of the top-left or A1 corner of the package against the top-left or A1 corner of the socket. By uniformly orienting the pins so as to bias the package towards a single corner, the socket provides consistency in how the electrical pads come into contact with the pins and arrive at a final resting point. Where a typical socket includes hundreds or thousands of small pins of a very small size (e.g., around a hundred micromillimeters (μm) in width), each of the plurality of pins aligns with the corresponding electrical pad in order to provide an effective electrical connection. Indeed, even one pin losing contact with the pad can result in chip failure.

In addition, by choosing the datum structure for positioning the pins to be a first corner (e.g. A1 corner) within a socket structure, implementations of the socket described herein provide a physical structure against which a chip package can be placed or biased to prevent certain directional movement as the chip is placed and after the chip is secured within a cavity of the socket. Where chip packages are often prone to move in an up-down direction and/or a left-right direction within the socket (translational movement), and/or the chip packet may rotate around an axis (rotational movement), this small movement may result in chip failure when one or more of the pins do not contact the corresponding electrical pad. This is further an improvement over conventional sockets in which pins are mapped or otherwise located relative to a central origin (e.g., a center point of the socket) or reference (e.g., datum) in which the locations of the pins are misaligned with respect to the centers of the package pads within the socket due to movement of the chip package described previously.

The combination of uniformly orienting the pins to wipe in the same direction so as to bias the chip package against the first (A1) corner, in conjunction with using the first (A1) corner as the origin for the positioning of the pins within the socket structure provides additional flexibility for accommodating dimensional variations of the chip package sizes relative to dimensional variations of the socket cavity sizes. Conventionally, a socket and the chip package are intentionally manufactured to be of similar sizes so as to prevent the chip package from moving within the socket cavity. However, manufacturing tolerances and assembly requirements typically dictate that the socket cavity be designed to be slightly oversized in relation to the chip package size. This then allows for translational and/or rotational movement of the chip package to occur within the socket cavity. Manufacturing tolerances can vary depending on the process capabilities of the socket and chip package manufacturers and their ability to control the socket cavity and chip package sizes. Assembly tolerances are dependent on the factory capability to precisely position the chip package within the socket cavity without interference or jamming. It can be appreciated that the socket cavity sizes and the chip package sizes vary from manufacturer to manufacturer.

In addition to providing uniform wiping in the same direction (e.g., a same uniform direction) so as to bias the chip package towards the first corner of the socket apparatus, sockets and methods described herein provide corner datum reference points for both the chip package and for the socket apparatus which are now made coincident. This allows different sized chip packages to be biased towards a first corner of sockets that could be of different sizes so as to allow an electrical connection between the plurality of pins located on the socket and the plurality of electronic pads located on the chip package. Indeed, by providing this corner datum reference, implementations described herein provide significant flexibility in the types of chip packages that can connect to a socket even where the chip package has significantly different dimensions from the socket structure.

As illustrated in the foregoing discussion, the present disclosure utilizes a variety of terms to described features and advantages of one or more embodiments of the socket apparatus and methods for facilitating electrical connections between pads on a chip package with components on a circuit board via the socket apparatus. Additional detail will now be provided regarding the meaning of some of these terms. Further terms will also be discussed in detail in connection with one or more embodiments and specific examples below.

In one or more embodiments described herein, a socket (or simply “socket”) includes a socket cavity. As used herein, a “socket cavity” refers to a structure or series of structures that provide an opening or area within which a chip package may be placed to connect a set of contacts on the chip package with a corresponding set of pins on the socket. The socket cavity may refer to a square or rectangular opening having walls and corners that define a perimeter of the socket. In one or more embodiments, the socket cavity may include one or more corners without socket walls in a manner that the chip package is only partially enclosed within an area of a top surface defined by the socket.

In one or more embodiments described herein, a socket includes a plurality of pins. As used herein, a “pin” refers to a contact point on a top surface of a socket that can form an electrical connection with electrical pads on a surface (e.g., contact surface) of the chip package. As will be discussed in further detail below, a pin may be part of a grid or array of pins that are uniformly oriented on a top surface of the socket and which provide a plurality of electrical points of connection with various components on a circuit board. In one or more embodiments described herein, the pins may refer to uniformly oriented pins that are angled (e.g., deflect, uniformly angled or oriented) in parallel to a diagonal of the socket cavity and towards a corner (e.g. A1 corner) of the socket and which cause a wiping motion or biasing force to be applied in a direction in which the uniformly oriented and deflected pins are angled. As used herein, the pins being oriented towards a first corner may refer to pins that are collinear with or parallel to a diagonal of the socket cavity towards the first (A1) corner such that a wiping motion is along the direction of the orientation.

As used herein, a “chip package” may refer to a variety of chip packages having contacts that can be placed within a socket to establish electrical connections between contacts on the chip package with components on a circuit board. Examples include a ball grid array (BGA) chip, chip scale package (CSP) chips, single in-line package (SIP) chips, and any chip packages having a plurality of contacts that can be placed in contact with a plurality pins within a socket to establish an electrical connection between the chip package and component(s) on the circuit board. As used herein a circuit board may refer to any board containing an electric circuit, such as a printed circuit board (PCB), an integrated circuit, a field-programmable gate array (FPGA), a motherboard, or any other board on which electrical components are housed and which provides electrical channels through which the components can communicate electrically.

In one or more embodiments, a plurality of pins may have a pin orientation in which the pins on the socket are located or otherwise oriented relative to an origin or reference point. As used herein, a “pin orientation” refers to a configuration of pins in which a location of each pin is identified or otherwise positioned on a surface of the socket relative to a datum reference. In one or more embodiments described herein, the datum reference refers to a point of reference at a first corner of the socket (e.g., rather than a central datum reference).

Additional detail will now be provided in connection with a socket apparatus and methods for facilitating electrical connections between a chip package and a circuit board via the socket apparatus in connection with illustrated examples. It will be appreciated that the implementations shown in the figures are provided by way of example and are not intended to be limiting to those implementations shown. Indeed, many of the examples provide simplified implementations of the socket to illustrate features of the socket that accomplish one or more of the benefits described above.

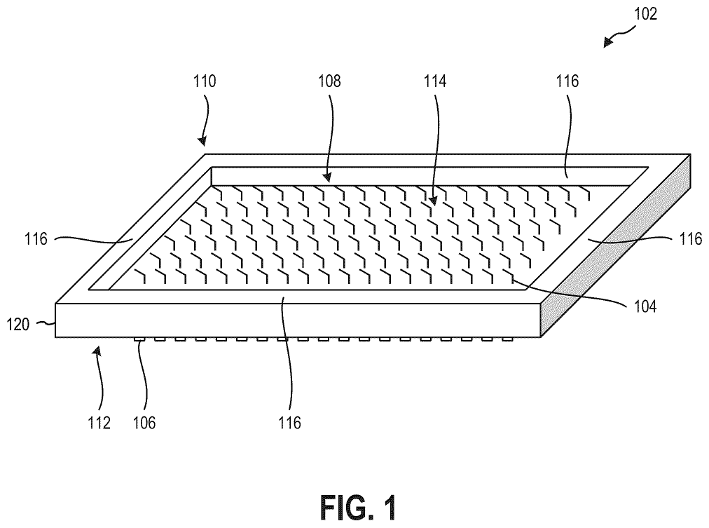

FIG. 1 illustrates an example of a socket apparatus 102 (or simply, “socket 102”), in accordance with one or more embodiments. In one or more embodiments, the socket apparatus 102 includes a top surface 114 and a bottom surface 112. As shown in FIG. 1, the surface 114 is opposite from the bottom surface 112. As will be discussed in further detail below, the top surface 114 is generally associated with a surface that is facing contacts of a chip package while the bottom surface 112 is mounted to a circuit board.

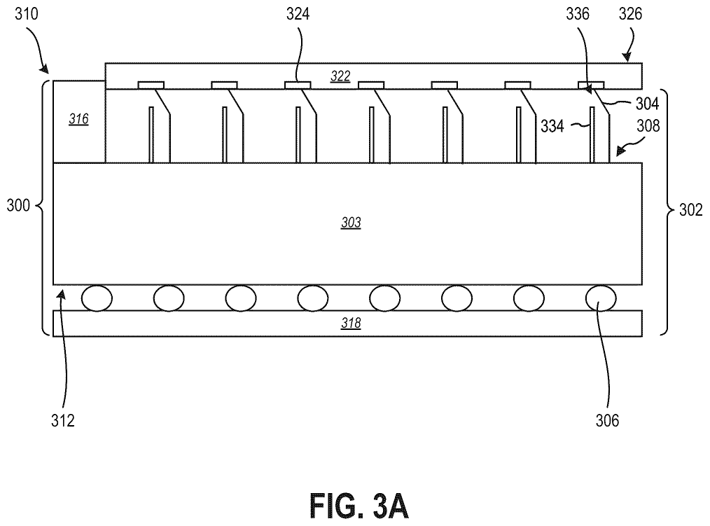

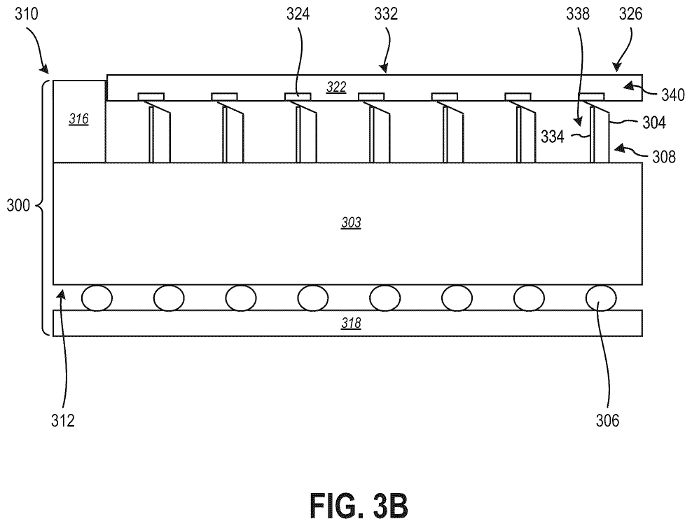

In one or more embodiments, the socket apparatus 102 includes a socket cavity 108 sized and configured to receive a chip package. In one or more embodiments, the socket cavity 108 includes a full enclosure of the socket apparatus 102. For example, as shown in FIG. 1, the socket apparatus 102 includes side structures 116 on the top surface 114 of each four sides of the socket apparatus 102. In one or more embodiments, the socket cavity 108 includes a partial enclosure of the socket apparatus. For example, the partial enclosure may include at least a side structure around the first corner of the socket structure, as further discussed in connection with FIGS. 3A and 3B.

In one or more embodiments, the socket apparatus 102 includes a socket housing 120. The socket housing 120 may be made using a variety of materials in accordance with various embodiments. For example, the socket housing can be made of polyphenylene sulfide (PPS), polyethylene terephthalate (PET), polybutylene terephthalate (PBT), polycyclohexylenedimethylene terephthalate (PCT), liquid crystalline polymer (LCP), or any other type of material. In one or more embodiments, the socket housing 120 is made using a non-conductive material.

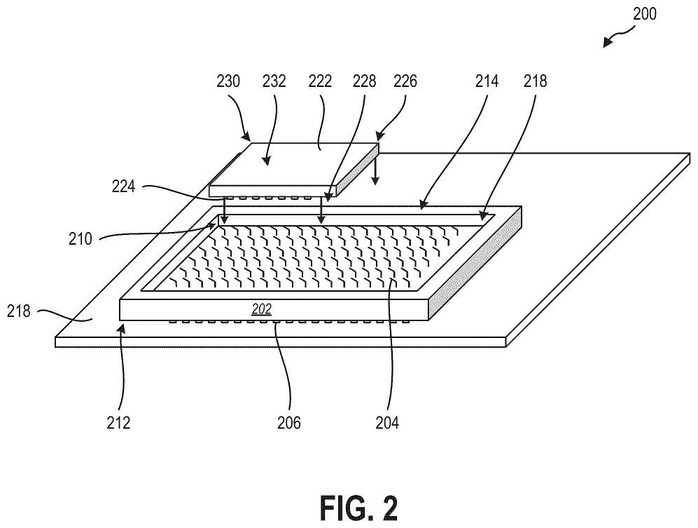

As shown in FIG. 1, the socket apparatus 102 further includes a plurality of base contacts 106 (e.g., paddles) on the bottom surface 112 of the socket apparatus 102. In one or more embodiments, the plurality of base contacts 106 are mountable on a circuit board, which will be discussed in further detail in connection with FIG. 2. The plurality of base contacts 106 may be flat, thin, and elongated metal pieces that provide a transmission path to the circuit board.

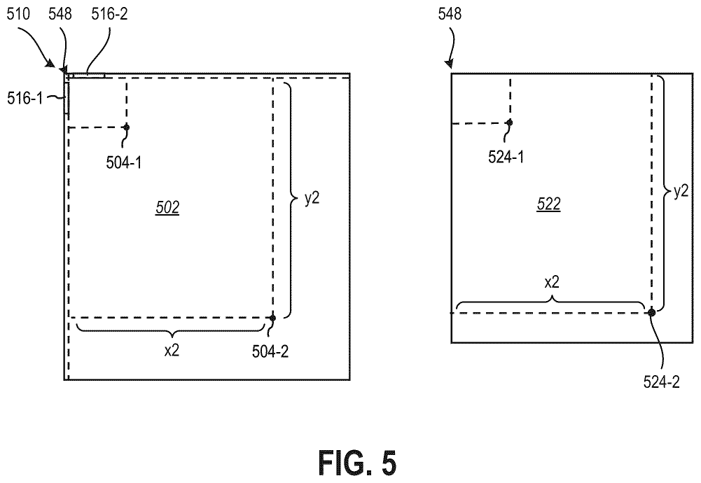

As shown in FIG. 1, the socket apparatus 102 further includes a plurality of pins 104. In one or more embodiments, the plurality of pins 104 are positioned across the top surface 114 of the socket apparatus 102. In one or more embodiments, the plurality of pins 104 are connected to the plurality of base contacts 106. In one or more embodiments, the plurality of pins 104 and the plurality of base contacts 106 provide a path for transmission of a signal or a power between a circuit board and a chip package. For example, the plurality of pins 104 may be made of a conductive metal or alloy. In one or more embodiments, the plurality of pins 104 have locations that are referenced relative to a datum reference. In this and other examples, the datum reference is positioned in a first corner 110 of the socket apparatus 102. Other implementations may involve the datum reference being positioned in a different corner of the socket apparatus 102. Additional details of the datum reference and the locations of the pins relative to the datum reference are further discussed in connection with FIG. 5.

FIG. 2 illustrates an example of a circuit board package 200, in accordance with one or more embodiments. As shown in FIG. 2, the circuit board package 200 includes a circuit board 218 and a socket 202. For example, the circuit board 218 may be a printed circuit board (PCB). In another example, the circuit board 218 may be a motherboard into which other circuit boards may be connected. In one or more embodiments, the socket 202 may be the socket 102 as described in connection to FIG. 1.

As noted above, the socket 202 may include a top surface 214 and a bottom surface 212 with the top surface 214 being an opposite surface to the bottom surface 212. In one or more embodiments, the socket 202 is mounted to the circuit board 218 via a plurality of base contacts 206 on the bottom surface 212 of the socket 202. For example, the socket 202 may be mounted to the circuit board 218 via soldering balls or other electrical mountings. In one or more embodiments, the socket 202 includes a ball grid array (BGA) socket interface (e.g., BGA packaging).

As shown in FIG. 2, the socket 202 includes a socket cavity 208 sized and configured to receive a chip package 222. In one or more embodiments, the size of the socket cavity 208 is larger than the size of the chip package 222. As a non-limiting example, the width and length of the socket cavity may be 0.50 mm×60 mm, while the width and length of the chip package 222 may be 40 mm×50 mm. Other implementations of the chip package 222 may be any set of dimensions that fit within the dimensions of the socket cavity.

As shown in FIG. 2, the socket 202 includes a plurality of pins 204 positioned across the top surface 214 of the socket 202. In one or more embodiments, the plurality of pins 204 have a location in the socket 202 that is referenced relative to a datum reference. As noted above, and as will be discussed below, the datum reference may be positioned in a first corner 210 of the socket 202.

In one or more embodiments, the chip package 222 includes a top surface 226 and a bottom surface 228. The bottom surface 228 of the chip package 222 includes a plurality of electrical pads 224. The plurality of electrical pads 224 have a location in the chip package 222 that is referenced relative to a datum reference. As shown in FIG. 2, the datum reference can be positioned in a first corner 230 of the chip package 222.

In one or more embodiments, the plurality of pins 204 includes a plurality of uniformly oriented pins deflecting in same direction and parallel to one another. In one or more embodiments, a uniformly oriented pin is a pin having a top portion (e.g., a deflected tip) in order to provide better electrical connection with the electrical pad 224 of the chip package 222. In one or more embodiments, the plurality of uniformly oriented pins are oriented (e.g., angled, or deflected) in an angle that is parallel to a diagonal of the socket cavity passing through and towards the first corner 210 of the socket 202. Additional details in connection with the angles of the pins 204 will be discussed below in connection with FIGS. 3A-3B.

In one or more embodiments, the chip package 222 may be placed within the socket cavity 208. When placed in the socket cavity 208, the plurality of electrical pads 224 may be positioned to come into contact with the plurality of uniformly oriented pins 204, particularly when placed such that the first corner of the chip package 222 and the first corner of the socket 202 are aligned.

In one or more embodiments, the plurality of uniformly oriented pins 204 are configured such that a wiping motion occurs when the electrical pads 224 come into contact with the uniformly oriented pins 204. In particular, due to the angled tips (deflated) of the uniformly oriented pins 204, the electrical pads may come into contact with the pins 204 at an initial contact point and wipe in a direction to a final resting point. Ideally, the initial contact point and the final resting point are within respective areas of the plurality of electrical pads 224. In one or more embodiments, the uniformly oriented pins 204 are each uniformly angled (deflected) in an angle that is parallel to a diagonal of the socket cavity passing through and towards the first corner such that the wiping direction is in the same direction (e.g., towards the first corner) for each of the pins 204, providing consistency in the ultimate placement between the pads 224 and pins 204 and additional reliability in the electrical connection established between the chip package 222 and components of the circuit board 218.

In one or more embodiments, a load 232 is applied on the top surface 226 of the chip package 222. In one or more embodiments, when a load is applied on the top surface 226 of the chip package 222, the plurality of uniformly oriented pins 204 are configured to flex in a uniform manner and cause the uniformly oriented pins 204 to wipe in a uniform direction. For example, the plurality of uniformly oriented pins 204 may wipe at an angle that is parallel to a diagonal of the socket cavity passing through and towards the first corner 210 of the socket 202.

FIGS. 3A and 3B illustrate a sideview of a circuit board package 300 establishing an electrical connection with a chip package 322 through a socket 302, in accordance with one or more embodiments. As shown in FIGS. 3A and 3B, the circuit board package 300 includes a circuit board 318 and a socket 302. In the example shown in FIGS. 3A-3B, a socket body 303 is connected to the circuit board 318 via a plurality of base contacts 306 positioned on the bottom surface 312 of the socket 302 in which the plurality of base contacts 306 are soldered to the circuit board 318. While not shown in FIGS. 3A-3B, the base contacts 306 be inclusive of a plurality of electrical contacts on a bottom surface of the socket 302 that is mounted to the circuit board 318 via a corresponding plurality of soldering balls or other mounting mechanisms.

As shown in the illustrated example, the socket 302 includes a socket cavity 308 that forms at least a partial enclosure around a top surface of the socket 302. As shown in FIGS. 3A and 3B the partial enclosure may include at least a side structure 316 around the first corner 310 of the socket 302. In this example, the side structure 316 may refer to a first corner of the socket cavity 308 to illustrate the direction in which a plurality of uniformly oriented pins are angled or otherwise oriented.

As shown in FIGS. 3A and 3B, the socket 302 includes a plurality of pins 304 and a plurality of pin supports 334. The plurality of pins 304 are configured to bend and come to rest against the plurality of pin supports 334 when a load 332 is applied to a top surface of the chip package 322, as shown in FIG. 3B. In one or more embodiments, the plurality of pin supports 334 are further configured to prevent the chip package 322 from flexing beyond a threshold angle and approaching a top surface of the socket 302 (i.e., a top surface of the socket base 303, as shown in FIG. 3B.

In one or more embodiments, the plurality of pins 304 include a plurality of uniformly oriented pins. In one or more embodiments, a uniformly oriented pin is a pin having a top portion or tip (e.g., a biased tip) in an effort to provide a more reliable electrical connection with the electrical pad 324 of the chip package 322 than would be provided with a non-uniformly oriented pin. As shown in FIGS. 3A and 3B, the plurality of uniformly oriented pins 304 are angled or otherwise oriented in an angle that is parallel to a diagonal of the socket cavity passing through and towards the first corner 310 of the socket 302.

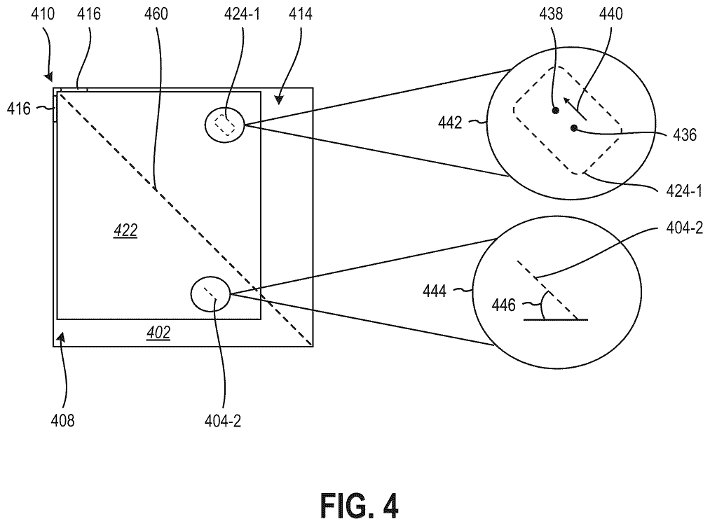

In one or more embodiments, the chip package 322 may be placed within the socket cavity 308. When placed within the socket cavity 308, the plurality of electrical pads 324 may be configured to come into contact with the plurality of uniformly oriented pins 304, as shown in FIG. 3B. As shown in FIG. 3B, the plurality of uniformly oriented pins 304 are configured to cause a wiping motion between an initial contact point 336 and a final resting point 338 on the electrical pads 324. As shown in FIGS. 3A-3B, the initial contact point 336 and the final resting point 338 are both within the same electrical pad of the plurality of electrical pads 324, which is discussed in further detail connection with FIG. 4 and FIG. 5.

As shown in FIG. 3B, a load 332 is applied on the top surface 326 of the chip package 322. In one or more embodiments, when the load 332 is applied on the top surface 326 of the chip package 322, the plurality of uniformly oriented pins 304 are angled or otherwise configured to wipe in a uniform direction 340. In the example shown in FIGS. 3A and 3B, the plurality of uniformly oriented pins 304 wipe in a uniform direction towards the first corner 310 of the socket 302.

FIG. 4 illustrates a top-down view of a socket apparatus 402 and a chip package 422 having a datum reference positioned in the first corner 410 of the socket apparatus 402, in accordance with at least one or more embodiments. In one or more embodiments, the socket apparatus 402 includes a corner structure 416 on the top surface 414 of the socket apparatus 402. In one or more embodiments, a socket cavity 408 includes a partial enclosure of the socket apparatus 402. In the embodiments shown in FIG. 4, the partial enclosure includes a corner structure 416 around the first corner 410 of the socket apparatus 402.

In one or more embodiments, the chip package 422 includes plurality of electrical pads and the socket apparatus 402 includes plurality of uniformly oriented pins, where the plurality of electrical pads and the plurality of uniformly oriented pins are configured to connect (e.g., come into physical contact) when a load (e.g., a downward load) is applied to the chip package 422. Each of the plurality of electrical pads and the plurality of uniformly oriented pins have a location that is referenced relative to a datum reference. In the embodiment shown in FIG. 4, the datum reference is positioned in a first corner 410 of the socket apparatus 402. Positions of the plurality of electrical pads and the plurality of uniformly oriented pins are further discussed in connection with FIG. 5.

The plurality of electrical pads 424 are positioned on the bottom surface of the chip package 422, and oriented at an angle that is parallel to a diagonal 460 of the socket cavity passing through and towards the datum reference point (e.g., the first corner). For example, when a nominal length of the chip package is the same as its nominal width, the electrical pads 425 are positioned in a 45-degree angle (e.g., parallel to or colinear with the 45-degree angle) towards the datum reference point. FIG. 4 provides a magnified view 442 of an electrical pad 424-1 that has been positioned in relation to the datum reference that is positioned in the first corner 410 of the socket apparatus 402. It should be noted that even if the electrical pad 424-1 has been shaped as a rectangular pad in FIG. 4, the plurality of electrical pads may be shaped in any other shapes as well.

FIG. 4 further provides a magnified view 444 of a uniformly oriented pin 404-2 that has been positioned in relation to the datum reference that is positioned in the first corner 410 of the socket apparatus 402. It can be seen that both the electrical pad 424-1 and the uniformly oriented pin 404-2 are at an angle 446 that is parallel to a diagonal 460 of the socket cavity passing through and towards the datum reference point (e.g., the first corner).

In one or more embodiments, when the chip package 422 is placed on top of the socket 402, the plurality of electrical pads are configured to come into contact with the plurality of uniformly oriented pins. When the chip package 422 and the socket apparatus 402 first come in contact with each other, a uniformly oriented pin 404-1 (not shown) will contact the electrical pad 424-1 at an initial contact point 436.

When a load is applied to the chip package 422, the uniformly oriented pin 404-1 is configured to wipe in a uniform direction 440 that is parallel to a diagonal of the socket cavity passing through and towards the first corner, from the initial contact point 436 to a final resting point 438, as shown in FIG. 4. In one or more embodiments, each of the plurality of uniformly oriented pins are configured to wipe each of the plurality of electrical pads between the initial contact point and the final resting point in an angle that is parallel to a diagonal 460 of the socket passing through and towards the datum reference point, such that the body of the chip package 422 (e.g., a center of mass of the chip package 422) moves towards the first corner 410 of the socket apparatus 402. The initial contact point and the final resting point are within the same electrical pad, as shown by the magnified view 442.

FIG. 5 illustrates an example of a corner datum reference point 548, in accordance with at least one or more embodiments. As shown in FIG. 5, the socket 502 includes side structures 516-1 and 516-2 that collectively form a corner structure of the socket 502 (e.g., the socket cavity). A corner datum reference point 548 is positioned in the first corner 510 of the socket 502. Similarly, the corner datum reference point 548 is positioned in the first corner of the chip package 522. The corner datum reference point 548 is the location from which each of the plurality of pins and each of the plurality of electrical pads are referenced. For example, a pin 504-1 is located on the socket 502 a length x1 and a length y1 away from the corner datum reference point 548.

Similarly, an electrical pad 524-1 is located on the chip package 522 a length x1 and a length y1 away from the corner datum reference point 548. When the chip package 522 is biased in the first corner 510 of the socket 502, the pin 504-1 and the electrical pad 524-1 will align to provide an electrical connection. Similarly, a pin 504-2 and electrical pad 524-2 are both located a length x2 and a length y2 away from corner datum reference point 548. Each pin location on the socket 502 and each electrical pad 524 on the chip package 522 is similarly located using the same corner datum reference point 548, which acts as a reference for each of the pins of the socket 502.

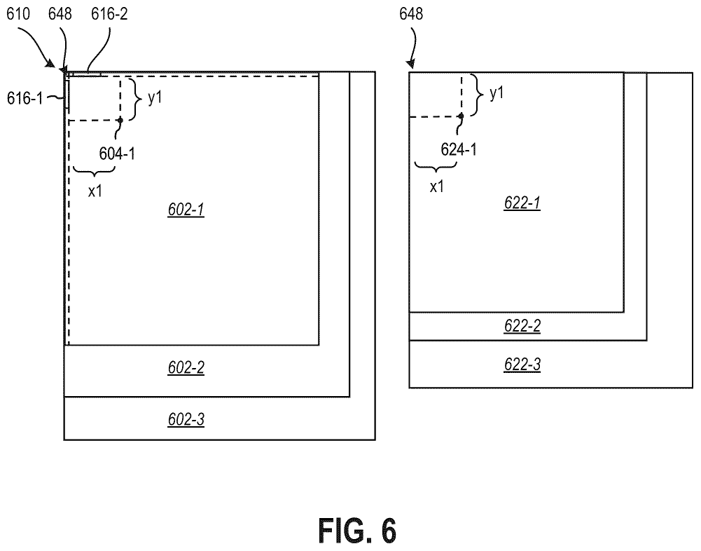

FIG. 6 illustrates an example showing different sized sockets (602-1, 602-2, and 602-3) and different sized chip packages (622-1, 622-2, and 622-3), in accordance with one or more embodiments. Each of the different sized sockets (602-1, 602-2, and 602-3) include the same corner datum reference point 648, meaning that each of the sockets (602-1, 602-2, and 602-3) include a pin 604-1 at a same distance away from the corner datum reference point 648.

Similarly, each of the different sized chip packages (622-1, 622-2, and 622-3) include an electrical pad 624-1 at a same distance away from the same corner datum reference point 648. Hence, the size of the socket 602 and the size of the chip package 622 may be independent from one another, so long as the chip package 622 includes biasing (e.g., due to the uniformly oriented pins and/or manual placement of the package within the socket) towards the first corner 610.

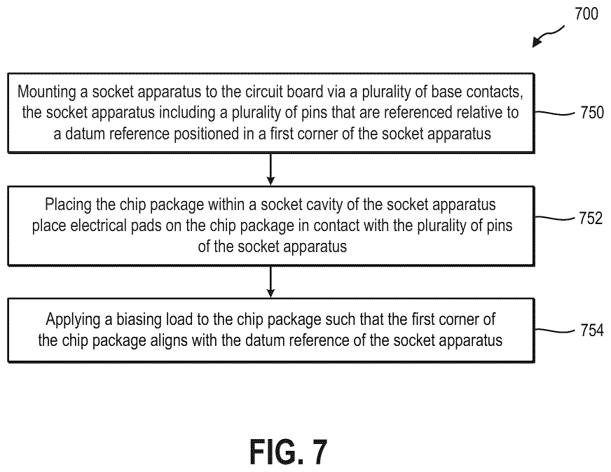

FIG. 7 illustrates a series of acts 700 for facilitating an electrical connection between a circuit board and a chip package, in accordance with one or more embodiments. While FIG. 7 illustrates acts according to one or more embodiments, alternative embodiments may omit, add to, reorder, and/or modify any of the acts shown in FIG. 7. The acts of FIG. 7 can be performed as part of a method. Alternatively, a system can perform the acts of FIG. 7.

As shown in FIG. 7, the series of acts 700 may include an act 750 of mounting a socket apparatus to the circuit board via a plurality of base contacts on a bottom surface of the socket apparatus, the socket apparatus including a plurality of pins positioned across a top surface of the socket apparatus opposite the bottom surface, each pin of the plurality of pins having a location that is referenced relative to a datum reference, wherein the datum reference is positioned in a first corner of the socket apparatus.

The series of acts 700 may further include an act 752 of placing the chip package within a socket cavity of the socket apparatus to position a plurality of electrical pads on the chip package in contact with the plurality of pins on the top surface of the socket apparatus. In one or more embodiments, the plurality of pins comprises a plurality of uniformly oriented pins that, when electrical pads of the chip package come into contact with the plurality of uniformly oriented pins and apply a load to the top surface of the socket apparatus, the plurality of uniformly oriented pins are configured to wipe in a uniform direction towards the first corner of the socket apparatus. In one or more embodiments, each of the electrical pads of the plurality of electrical pads of the chip package has a location that is referenced relative to a datum reference, wherein the datum reference is positioned in a first corner of the chip package. In one or more embodiments, the chip package is a land grid array (LGA) package.

The series of acts 700 may further include an act 754 of applying a biasing load to the chip package such that the first corner of the chip package aligns with the first corner of the socket apparatus. In one or more embodiments, the biasing load is caused by a combination of physical placement of the chip package in the first corner of the socket apparatus and wiping of the plurality of uniformly oriented pins towards the first corner of the socket apparatus.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium comprising instructions that, when executed by at least one processor, perform one or more of the methods described herein. The instructions may be organized into routines, programs, objects, components, data structures, etc., which may perform particular tasks and/or implement particular data types, and which may be combined or distributed as desired in various embodiments.

The steps and/or actions of the methods described herein may be interchanged with one another without departing from the scope of the claims. In other words, unless a specific order of steps or actions is required for proper operation of the method that is being described, the order and/or use of specific steps and/or actions may be modified without departing from the scope of the claims.

The term “determining” encompasses a wide variety of actions and, therefore, “determining” can include calculating, computing, processing, deriving, investigating, looking up (e.g., looking up in a table, a database, or another data structure), ascertaining and the like. Also, “determining” can include receiving (e.g., receiving information), accessing (e.g., accessing data in a memory) and the like. Also, “determining” can include resolving, selecting, choosing, establishing and the like.

The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element or feature described in relation to an embodiment herein may be combinable with any element or feature of any other embodiment described herein, where compatible.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A socket apparatus, comprising:
a socket cavity sized and configured to receive a chip package;
a plurality of base contacts on a bottom surface of the socket apparatus, the plurality of base contacts being mountable on a circuit board; and
a plurality of pins positioned across a top surface of the socket apparatus opposite the bottom surface, each pin of the plurality of pins having a location that is referenced relative to a datum reference, wherein the datum reference is positioned in a first corner of the socket apparatus.

2. The socket apparatus of claim 1, wherein the plurality of pins comprises a plurality of uniformly oriented pins deflecting in a uniform direction and parallel to one another, such that when a plurality of electrical pads of the chip package come into contact with the plurality of uniformly oriented pins and a load is applied to the top surface of the socket apparatus, the plurality of uniformly oriented pins are configured to wipe in a uniform direction towards the first corner of the socket apparatus.

3. The socket apparatus of claim 2, wherein the plurality of uniformly oriented pins is configured to wipe between initial contact points and final resting points in which a direction between the initial contact points and the final resting points is towards the first corner of the socket apparatus parallel to a diagonal of the socket cavity.

4. The socket apparatus of claim 3, each initial contact point and each final resting point of the plurality of uniformly oriented pins are within an area of a corresponding electrical pad from the plurality of electrical pads.

5. The socket apparatus of claim 2, wherein a top portion of each uniformly oriented pin of the plurality of uniformly oriented pins is angled in parallel to a diagonal of the socket cavity extending from the first corner of the socket apparatus, wherein an angling of the top portion is parallel to the diagonal of the socket cavity and causes the biasing pin to flex in a uniform direction parallel to the diagonal towards the first corner while applying the load to the top surface of the socket apparatus.

6. The socket apparatus of claim 1, wherein the socket cavity includes one or more of:
a partial enclosure of the top surface of the socket apparatus, the partial enclosure including at least a corner structure around the first corner of the socket apparatus; or
a full enclosure of the socket apparatus.

7. The socket apparatus of claim 1, wherein the plurality of base contacts and the plurality of pins are part of a continuous member having solder balls added to the base plurality of base contacts to solder the continuous member to the circuit board.

8. The socket apparatus of claim 1, wherein the socket apparatus has a first size, and wherein the chip package has a second size having a set of dimensions that are smaller than the first size such that the chip package fits within the socket cavity of the socket apparatus.

9. The socket apparatus of claim 1, wherein the socket apparatus includes a ball grid array (BGA).

10. The socket apparatus of claim 1, wherein the chip package is a land grid array (LGA) package.

11. A circuit board package, comprising:
a circuit board; and
a socket apparatus mounted to the circuit board via a plurality of base contacts on a bottom surface of the socket apparatus, the socket apparatus comprising:
a socket cavity sized and configured to receive a chip package; and
a plurality of pins positioned across a top surface of the socket apparatus opposite the bottom surface, each pin of the plurality of pins having a location that is referenced relative to a datum reference, wherein the datum reference is positioned in a first corner of the socket apparatus.

12. The circuit board package of claim 11, wherein the plurality of pins comprises a plurality of uniformly oriented pins deflecting in a uniform direction and parallel to one another, such that when a plurality of electrical pads of the chip package come into contact with the plurality of uniformly oriented pins and a load is applied to the top surface of the socket apparatus, the plurality of uniformly oriented pins are configured to wipe in a uniform direction towards the first corner of the socket apparatus.

13. The circuit board package of claim 11, wherein each electrical pad of a plurality of electrical pads of the chip package has a location that is referenced relative to the datum reference, wherein the datum reference is positioned in the first corner of the chip package that aligns with the first corner of the socket apparatus when the chip package is placed within the socket cavity.

14. The circuit board package of claim 11, wherein the first corner of the chip package and the first corner of the socket apparatus is a same physical corner.

15. The circuit board package of claim 11, wherein the chip package is a land grid array (LGA) package, and wherein the socket apparatus includes a ball grid array (BGA).

16. The circuit board package of claim 11, wherein the plurality of pins is configured to wipe between an initial contact point and a final resting point in which a direction between the initial contact point and the final resting point is parallel to a diagonal of the socket cavity passing through and toward the first corner of the socket apparatus.

17. A method of facilitating an electrical connection between a circuit board and a chip package, comprising:
mounting a socket apparatus to the circuit board via a plurality of base contacts on a bottom surface of the socket apparatus, the socket apparatus including a plurality of pins positioned across a top surface of the socket apparatus opposite the bottom surface, each pin of the plurality of pins having a location that is referenced relative to a datum reference, wherein the datum reference is positioned in a first corner of the socket apparatus;
placing the chip package within a socket cavity of the socket apparatus to position a plurality of electrical pads on the chip package in contact with the plurality of pins on the top surface of the socket apparatus; and
applying a biasing load to the chip package such that the first corner of the chip package aligns with the first corner of the socket apparatus.

18. The method of claim 17, wherein the plurality of pins comprises a plurality of uniformly oriented pins deflecting in a uniform direction and parallel to one another, such that when a plurality of electrical pads of the chip package come into contact with the plurality of uniformly oriented pins and the biasing load is applied to the top surface of the socket apparatus, the plurality of uniformly oriented pins are configured to wipe in a uniform direction towards the first corner of the socket apparatus.

19. The method of claim 18, wherein the biasing load is caused by a combination of physical placement of the chip package in the first corner of the socket apparatus and wiping of the plurality of uniformly oriented pins in parallel to a diagonal of the socket cavity passing through and towards the first corner of the socket apparatus.

20. The method of claim 18, wherein the plurality of uniformly oriented pins are configured to wipe between an initial contact point and a final resting point in which a direction between the initial contact point and the final resting point is parallel to a diagonal of the socket cavity passing through and towards the first corner of the socket apparatus.
